(19) United States
(12) Patent Application Publication
(10) Pub. No.: US 2012/0081132 A1
(43) Pub. Date: Apr. 5, 2012

(54) Measuring Minority Carrier Lifetime

(75) Inventors: Francisco Machuca, Oakland, CA (US); Ronald Chiarello, Lafayette, CA (US); G. Lorimer Miller, Eastham, MA (US); Joseph W. Foster, San Jose, CA (US); David C. Tigwell, Houston, TX (US)

(73) Assignee: MKS Instruments, Inc., Andover, MA (US)

(21) Appl. No.: 13/080,451

(22) Filed: Apr. 5, 2011

Related U.S. Application Data
(63) Continuation-in-part of application No. PCT/US11/20783, filed on Jan. 11, 2011.
Application No. PCT/US11/20783 is a continuation of application No. 12/687,855, filed on Jan. 14, 2010.
Application No. 12/687,855 is a continuation-in-part of application No. 12/687,855, filed on Jan. 14, 2010.

(51) Int. Cl. G01R 27/28; H01F 17/06

(52) U.S. Cl. 324/655; 336/105

(57) ABSTRACT

An apparatus includes a member including a ferromagnetic material, an inductance-capacitance resonant circuit, a substrate disposed relative to the member, and a plurality of radiation sources. The member includes a post disposed at its center and a surface extending to an outer wall. The member defines a gap between the post and the outer wall. The inductance-capacitance resonant circuit is configured to resonate at a measurement frequency. The circuit includes an inductor disposed relative to the post. The substrate is disposed relative to the member. The substrate is electromagnetically coupled to the inductor. The plurality of radiation sources is disposed radially outward from and circumferentially around the post of the member. The apparatus can be used to simultaneously measure conductance (inverse sheet resistance), steady state photoconductance, true steady state minority carrier lifetime, photoconductance build-up and photoconductance decay lifetime.

### CROSS-REFERENCE TO RELATED APPLICATIONS

This application is a continuation-in-part of International Application No. PCT/US11/20783 filed Jan. 11, 2011, in the U.S. Receiving Office, which claims priority to U.S. application Ser. No. 12/687,855 filed Jan. 14, 2010. This application is a continuation-in-part of U.S. application Ser. No. 12/687,855 filed Jan. 14, 2010. The disclosures of both applications are herein incorporated by reference in their entireties.

### FIELD OF THE INVENTION

The invention relates generally to semiconductor characterization tools, and, more particularly, to apparatuses and methods for measuring minority carrier lifetime in a semiconductor sample.

### BACKGROUND

Minority carrier lifetime is a quantity of fundamental importance for semiconductor materials. This quantity can provide an indication of the quality and defect density in raw semiconductor materials, and can also be used to monitor semiconductor device fabrication and processing. In the case of device fabrication monitoring, minority carrier lifetime measurements can be performed at one or more points within a fabrication process. Each step in a fabrication process can be expensive and time consuming. As such, it may be advantageous that the material that is subjected to testing is not degraded by the testing process, which degradation could cause the material to be reworked or discarded. It may also be advantageous that such “inline” measurements of minority carrier lifetime be relatively easily performed and understood, such that fabrication errors can be identified quickly, before time and resources are wasted performing further processing on already defective materials and before further good material is subjected to a malfunctioning fabrication process.

### SUMMARY OF THE INVENTION

A contactless analysis system has been developed that simultaneously and in real-time provides the steady state photoconductance, true steady state recombination lifetime (GTAU), photo-conductance build-up (PCB), photo-conductance decay (PCD) and sheet conductance (σ) measurements of semiconductor materials. The unique combination of GTAU and PCD into a single analysis system provides a symbiosis that enables the analysis system and methods described here to have significant advantages over the prior art. This includes, but is not limited to, improved SNR (signal to noise ratio), the capability to measure shorter minority carrier lifetimes, and the ability to self-calibrate. The GTAU measurement is advantageous in that it is has superior SNR and has ability to measure much shorter carrier lifetimes. However, GTAU has a limitation in some applications since it is a relative measurement. This limitation is overcome by combining the PCD measurement, which is an absolute measurement, with GTAU. In this way, the (absolute) PCD measurement is used to calibrate the GTAU measurement automatically. In summary, GTAU and PCD when used in this way are complimentary, with the PCD method serving to calibrate the GTAU method results and the GTAU method then providing much higher quality measurements over a larger range of minority carrier lifetimes. Alternatively, in cases where the prior calibration deviates in fabricated devices, unwanted reflection losses or defective processes can be determined by having both measurements available to cross reference.

In some embodiments, the measurement tool can detect both a traditional PCD and a “True Steady State” recombination lifetime. A programmable light emitting diode (LED) array can be used to distinguish the surface of the wafer from the bulk of the wafer. In various embodiments, a technique is disclosed to measure photo-conductance build-up (PCB). Shallow trap signatures can be detected by comparing the turn on to the turn off transient response of a semiconductor wafer. In this manner, the signature of trap states can be determined by comparing the assymetry in the PCB to PCD minority carrier lifetime, whereby PCD>>PCB indicates shallow trapping behavior. In addition, photoconductance data can be obtained from various depths in the wafer allowing minority carrier lifetime to be derived near surface as well as by fully probing throughout the thickness of the wafer by changing the LED illumination wavelength. A first advantage in changing penetration depth, is to allow the determination of the spatial extent of a defect relative to the absorption depth of the LED array. A second adavantage is to adjust the surface to bulk contribution to effective recombination lifetime by changing the distance to the incident surface by tuning the LED array color.

The fast turn on and fast cut off of LED's (e.g., on the order of about 10-800 nanosecond) can provide a clear advantage in measuring the transient photoconductance signal yielding both the PC build up signal and the PC decay signal. Furthermore, by using electronically addressable LED's, the diodes can be left on for long times compared to the recombination lifetime under test (e.g., 0.5 millisecond to 10 millisecond) to allow a true steady state photoconductance response curve to be produced. The measurement frequency can allow full wafer thickness to be probed using dual side illumination and paired with a shallow penetrating probe to get surface sensitive information. The varying illumination probes can be disposed opposite to each other or on the same side, and synchronized to measure at alternate times or simultaneously. This gives the recombination lifetime near surface within the penetration depth of the surface probe and completely through the bulk with the near-infrared (NIR) probe.

There is a distinct calibration advantage as well. PCD is an absolute measurement, and the temporal accuracy and its determination is set by the “state of the art” analog to digital converter and number of sampling points applied to rising and falling edges of the photoconductive signal in direct response to the modulated illumination. The Steady State (SS) and PCD lifetimes are simultaneously measured and a self calibration is achieved by comparing the resulting scatter plot between the two measurements at low light injection levels. A linear relationship exists, leading to a simple and elegant factory calibration without a need for measuring independently the generation rate. This allows a large dynamic range for measurements, (e.g., greater than 1-5 microsecond for PCB and PCD, and greater than 100 nanosecondsfor SS).

An advantage on measuring defect states leading to a trap state determination metric is facilitated by having PC build up and PC decay response. PCD is affected and PCB is relatively unaffected by shallow traps. A new trap state metric is measured by the deviations in buildup and recombination decay lifetime. The direct measurement of lifetime allows a fast sampling rate on board determination of PCB, PCD, and a relatively slow sampling rate, low noise bandwidth measurement of true steady state lifetime. The electronic response of the detection circuitry need not be deconvoluted in the latter, and the slow changing illumination response of a programmable flash lamp need not be removed as is a typical error for response of solar materials. This is an absolute and direct measurement of recombination lifetime without interference of the response time of your electronics or switching times of your light source. Lastly, sub band gap illumination allows for a simple bias light approach that is coincident with modulated illumination to quench trap states. In this manner, minority carrier lifetime can be measured with low light levels (e.g., 0.1 to 0.3 Suns) without high intensity bias light.

In one aspect, there is an apparatus including a member including a ferromagnetic material, an inductance-capacitance resonant circuit, a substrate disposed relative to the member, and a plurality of radiation sources. The member includes a post disposed at its center and a surface extending to an outer wall. The member defines a gap between the post and the outer wall. The inductance-capacitance resonant circuit is configured to resonate at a measurement frequency. The circuit includes an inductor disposed relative to the post. The substrate is disposed relative to the member. The substrate is electromagnetically coupled to the inductor. The plurality of radiation sources is disposed radially outward from and circumferentially around the post of the member.

In another aspect, there is a method that includes electromagnetically coupling a substrate into an inductance-capacitance resonant circuit formed from (i) a member comprising a ferromagnetic material, (ii) an inductor and (iii) the substrate; illuminating the substrate to cause photoconduction in the substrate; and measuring a drive current of the inductance-capacitance resonant circuit while illuminating to determine photoconductance build-up.

In yet another aspect, there is a method for measuring minority carrier lifetime from a plurality of depths within a substrate. The method includes electromagnetically coupling the substrate into an inductance-capacitance resonant circuit formed from (i) a member comprising a ferromagnetic material, (ii) an inductor and (iii) the substrate; illuminating the substrate with a first wavelength to probe a surface of the substrate; and illuminating the substrate with a second wavelength longer than the first wavelength to probe the bulk of the substrate.

In various embodiments, the plurality of radiation sources includes two circumferential rings disposed around the post. A first circumferential ring includes first sources having a first wavelength, and a second circumferential ring includes second sources having a second wavelength different than the first wavelength. In some embodiments, the plurality of radiation sources includes first sources having a first wavelength interleaved with second sources having a second wavelength different than the first wavelength. In certain embodiments, each radiation source includes a single housing including at least two light emitting diodes having different respective wavelengths.

The apparatus can include a second member including the ferromagnetic material. The second member includes a second post disposed at its center and a second surface extending to a second outer wall. The second member defines a second gap between the second post and the second outer wall. The substrate is disposed between the member and the second member. The apparatus can include a second plurality of radiation sources disposed radially outward from and circumferentially around the second post of the second member. The plurality of radiation sources has a first wavelength that is different than a second wavelength of the second plurality of radiation sources.

In certain embodiments, the plurality of radiation sources includes a first source having a first wavelength having a 90% penetration depth that is less than 20 micrometer and a second source having a second wavelength having a 90% penetration depth that is greater than 180 micrometer. The first source can have a first wavelength having a 90% penetration depth that is less than 3 micrometer.

Each radiation source can be a light emitting diode.

The drive current of the inductance-capacitance resonant circuit can be measured while switching the illumination to determine photoconductance: photoconductive rise, steady state, and decay. The substrate can be illuminated with above bandgap radiation and/or with sub-band gap radiation to populate any defect states of the substrate. The illumination can be modulated with a rise and fall time of less than or equal to 800 nanosecond (e.g., less than or equal to 100 nanosecond).

In still another aspect, there is an apparatus including a member including a ferromagnetic material. The member includes a post disposed at its center and a surface extending to an outer wall. The member defines a gap between the post and the outer wall. An inductance-capacitance resonant circuit is configured to resonate at a measurement frequency. The circuit includes an inductor disposed relative to the post. A substrate is disposed relative to the member. The substrate is electromagnetically coupled to the inductor. A plurality of ports is defined in the member radially outward from and circumferentially around the post of the member. A plurality of optical waveguides is coupled to one or more radiation sources. Each optical waveguide is configured to deliver the radiation to the substrate through one of the plurality of ports.

In various embodiments, the plurality of optical waveguides can include one of an optical fiber, an optical fiber bundle, a light guide, a liquid light guide, a reflective light guide or a hollow waveguide.

In some embodiments, the plurality of ports can include two circumferential rings disposed around the post. A first plurality of optical waveguides are coupled to a first source having a first wavelength. Each waveguide of the first plurality of optical waveguides is configured to deliver radiation from the first source to the substrate through one of the ports in a first circumferential ring. A second plurality of optical waveguides is coupled to a second source having a second wavelength. Each waveguide of the second plurality of optical waveguides is configured to deliver radiation from the second source to the substrate through one of the ports in a second circumferential ring.

In certain embodiments, the plurality of ports includes first ports interleaved with second ports. A first plurality of optical waveguides is coupled to a first source having a first wavelength. Each waveguide of the first plurality of optical waveguides is configured to deliver radiation from the first source to the substrate through one of the first ports. A second plurality of optical waveguides is coupled to a second source having a second wavelength. Each waveguide of the second plurality of optical waveguides is configured to deliver radiation from the second source to the substrate through one of the second ports.

The apparatus can include a second member including the ferromagnetic material. The second member includes a second post disposed at its center and a second surface extending to a second outer wall. The second member defines a second gap between the second post and the second outer wall. The substrate is disposed between the member and the second member. A second plurality of ports is defined in the second member radially outward from and circumferentially around the second post of the member. A second plurality of optical waveguides is coupled to one or more radiation sources. Each optical waveguide is configured to deliver the radiation to the substrate through one of the second plurality of ports. The radiation sources are coupled to the plurality of optical waveguides having a first wavelength that is different than a second wavelength of the radiation sources coupled to the second plurality of optical waveguides.

In another aspect, an apparatus, such as a minority carrier lifetime measurement tool, is provided. The apparatus can include a resonant circuit having an inductor and a capacitor and configured to resonate at a measurement frequency. The apparatus can also include a ferromagnetic core having a first portion and a second portion. The first portion can define a gap, and can be configured to direct therealong a magnetic field established by the inductor, such that lateral spreading of the magnetic field outside of the first portion is inhibited and the magnetic field is directed generally uniformly across the gap. For example, the inductor can include at least one coil that extends circumferentially around the first portion. The second portion can be configured to direct the magnetic field therealong and, in conjunction with the first portion, into a closed loop. The second portion may define a gap that is aligned with the gap defined by the first portion.

The first portion can define a longitudinal axis, and the ferromagnetic core can be generally radially symmetric about the longitudinal axis. In some embodiments, the ferromagnetic core can include opposing first and second parts, with the first part forming at least part of the first and second portions and the second part also forming at least part of the first and second portions. The first and second parts may be generally symmetrical across a plane directed along the gap defined by the first portion of the ferromagnetic core.

In some embodiments, the first and second parts may respectively include elongated bases and a central post extending from each of the elongated bases. A pair of side posts may extend from each of the elongated bases on opposing sides of, and generally parallel to, the central post, such that each of the first and second parts generally forms an “E” shape, said first portion including the central posts and the second portion including said side posts. In some embodiments, the first and second parts may respectively include generally planar bases, said first portion extends generally perpendicularly from said bases, and said second portion forms a generally annular flange extending generally perpendicularly from said bases and circumferentially around said first portion.

A radiation source can be configured to irradiate an area proximal to the gap defined by the first portion of the ferromagnetic core. For example, the radiation source can be configured to irradiate an area around the gap that is symmetric across a longitudinal axis defined by the first portion. The radiation source may include at least two light emitting diodes configured to emit radiation of respectively different wavelengths. The radiation source can include a light emitting diode that extends through one of the bases associated with the first and second parts and is disposed between the first portion and the flange formed by the second portion. In some embodiments, the radiation source may include at least two light emitting diodes that extend through respective ones of the bases and are respectively disposed between the first portion and the flange. The radiation source can include a plurality of light emitting diodes disposed circumferentially around the first portion and extending through one of the bases between the first portion and the flange, and can include another plurality of light emitting diodes similarly extending through another of the bases.

The radiation source is configured to emit radiation intermittently at a switching frequency. The apparatus may be configured to receive a sample of semiconductor material in the gap defined by the first portion of the ferromagnetic core. The radiation source can be configured to intermittently irradiate the sample with radiation configured to cause photoconductivity in the sample. The switching frequency can be on the order of or lower than the inverse of minority carrier lifetime for the sample. The resonant circuit can be associated with a measurement frequency voltage and can include a drive current source configured to provide a drive current that is adjustable so as to maintain the measurement frequency voltage across the resonant circuit constant. The apparatus may further include a data acquisition system configured to collect drive current values at times subsequent to commencing and halting irradiation of the sample by more than the inverse of minority carrier lifetime of the sample. The data acquisition system may also be configured to collect drive current values at a data collection frequency that is higher than the inverse of minority carrier lifetime for the sample and at times immediately subsequent to commencing and halting irradiation of the sample.

In another aspect, an apparatus is provided that includes a ferromagnetic core. The core can have a first portion that defines a gap and is configured to direct therealong a magnetic field established by an inductor coiled around the first portion, such that lateral spreading of the magnetic field outside of the first portion is inhibited, and to direct the magnetic field generally uniformly across the gap. A second portion of the core can be configured to direct the magnetic field there along and, in conjunction with the first portion, into a closed loop. A radiation source can be integrated into the ferromagnetic core.

In yet another aspect, a method is provided, such as a method for determining minority carrier lifetimes in semiconductor samples. The method includes providing an apparatus having a resonant circuit, a ferromagnetic core, and a radiation source. The resonant circuit can include an inductor and a capacitor and can be configured to resonate at a measurement frequency associated with a measurement frequency voltage across the resonant circuit. The ferromagnetic core can include a first portion that defines a gap and is configured to direct therealong a magnetic field established by the inductor, such that lateral spreading of the magnetic field outside of the first portion is inhibited, and to direct the magnetic field generally uniformly across the gap. The ferromagnetic core can also include a second portion configured to direct the magnetic field there along and, in conjunction with the first portion, into a closed loop. The radiation source can be configured to irradiate an area proximal to the gap defined by the first portion of the ferromagnetic core.

A sample can be electromagnetically coupled into the resonant circuit, a first portion of the sample being disposed in the gap such that a magnetic field established by the inductor extends generally uniformly through the first portion of the sample. A drive current of the resonant circuit can be adjusted to maintain constant the measurement frequency voltage. The sample can be intermittently, at a switching frequency, irradiated in an area proximal to the first portion, with radiation configured to cause photoconduction in the sample. The switching frequency can be on the order of or lower than the inverse of minority carrier lifetime for the sample.

The method may further include determining a minority carrier lifetime for the sample, for example, by measuring the drive current both while irradiating the sample and when the sample is not being irradiated. The drive current may be sampled at a sample rate that is higher than the inverse of minority carrier lifetime for the sample and at times immediately subsequent to commencing and halting irradiation of the sample. A functional approximation for temporal drive current data measured after halting irradiation of the sample and within a time equal to or longer than the inverse of minority carrier lifetime for the sample can be determined. The quasi-steady state drive current can be measured after commencing and halting irradiation of the sample to find a difference between the drive current under each set of conditions. This difference can be scaled and provided as an output.

In some embodiments, the sample can be intermittently irradiated with radiation of a first characteristic wavelength and subsequently intermittently irradiated with radiation of a second characteristic wavelength that is different from the first characteristic wavelength. In some embodiments, the sample can be repeatedly repositioned such that different portions of the sample are disposed in the gap defined by the first portion of the ferromagnetic core. The drive current can be repeatedly measured in response to each repeated repositioning of the sample.

In another aspect, an apparatus, such as a tool for measuring minority carrier lifetime in a semiconductor sample, is provided. The apparatus includes a ferromagnetic core including opposing first and second parts that define a gap therebetween. Each of said first and second parts may include a base, a generally annular flange extending from the base, and a tubular portion extending from the base and radially inside the flange. A first conductor coil can extend around the tubular portion associated with the first part, and a second conductor coil can extend around the tubular portion associated with the second part. A radiation source can be configured to irradiate at least a portion of the gap defined between said first and second parts, for example, so as to illuminate a wafer disposed in the gap. The first and second conductor coils can be configured to be connected in parallel to a variable power source, such that a magnetic field generated by the first conductor coil is generally aligned with a magnetic field generated by the second conductor coil. In some embodiments, the tubular portion may be transparent to radiation emitted from the radiation source.

In other examples, any of the aspects above, or any apparatus, system or device, or method, process or technique, described herein, can include any of the aforementioned features. Other aspects and advantages of the invention will become apparent from the following detailed description, taken in conjunction with the accompanying drawings, illustrating the principles of the invention by way of example only.

### BRIEF DESCRIPTION OF THE DRAWINGS

Having thus described the invention in general terms, reference will now be made to the accompanying drawings, which are not necessarily drawn to scale, emphasis instead generally being placed upon illustrating the principles of the invention.

FIG. 1 is a block diagram of a system for performing minority carrier lifetime measurements in a sample of semiconductor material.

FIG. 2 is a schematic view of a minority carrier lifetime measurement tool configured in accordance with an example embodiment.

FIG. 3 is a perspective view of a ferromagnetic core configured in accordance with an example embodiment.

FIG. 4 is a perspective view of the core of FIG. 3 sectioned along plane p of FIG. 3.

FIG. 5 is a partially exploded perspective view of the core of FIG. 4.

FIG. 6 is a top view of the core of FIG. 5 with the diffuser removed to reveal the underlying light emitting diodes.

FIG. 7 is a cross sectional view of the core of FIG. 3 sectioned along plane 7-7 of FIG. 3.

FIG. 8 is a cross sectional view of the core of FIG. 3, sectioned along plane 8-8 of FIG. 3.

FIG. 9 is a plan view of a core including radiation sources having different wavelengths.

FIG. 10 is a plan view of another core including radiation sources having different wavelengths.

FIG. 11 is a sectional view of a substrate and dual core including radiation sources having different wavelengths.

FIG. 12A is a plan view of a core including ports coupled to optical waveguides.

FIG. 12B is a sectional view of the core of FIG. 12A.

FIG. 13A is a plan view of another core including ports coupled to optical waveguides.

FIG. 13B is a sectional view of the core of FIG. 13A.

FIG. 14 is a sectional view of a substrate and dual core including ports coupled to optical waveguides.

FIG. 15 is a schematic view of a minority carrier lifetime measurement tool configured in accordance with another example embodiment.

### DETAILED DESCRIPTION

The present invention now will be described more fully hereinafter with reference to the accompanying drawings, in which some, but not all embodiments of the inventions are shown. Indeed, these inventions may be embodied in many different forms and should not be construed as limited to the embodiments set forth herein; rather, these embodiments are provided so that this disclosure will satisfy applicable legal requirements. Like numbers refer to like elements throughout.

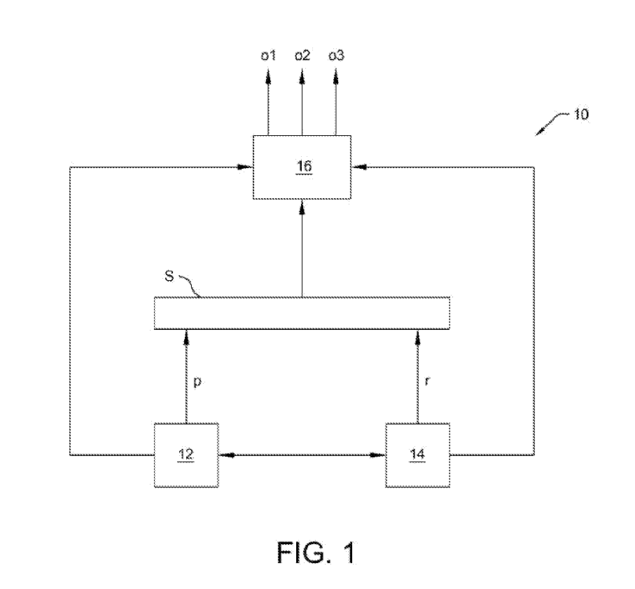

Referring to FIG. 1, therein is shown a schematic diagram of a system 10 for performing minority carrier lifetime measurements in a sample s of semiconductor material (“the sample”), the system being configured in accordance with an example embodiment. The system 10 includes a signal generation module 12 in communication with a radiation source module 14. As will be discussed further below, the signal generation module 12 acts to generate a probe signal p, for example, in the form of an oscillating electromagnetic field, with which the sample s interacts. As the sample s interacts with the probe signal p, the probe signal is attenuated by an amount related to (amongst other things) the minority carrier population in the sample. The signal generation module 12 may therefore include electrical components (both active and passive) and circuitry appropriate for generating the probe signal p. In some embodiments (discussed below), the signal generation module 12 may include structures, such as a sample interface, for effectively coupling the probe signal p and the sample s.

The radiation source module 14 may include a radiation source, such as one or more light emitting diodes (“LEDs”), for periodically irradiating r the sample s. As discussed in more detail later, some portion of the radiation r may be absorbed by the sample s, thereby causing a change in the minority carrier population in the sample. The radiation source module 14 may also include electronics for controlling the intensity of the radiation provided therefrom. For example, in some cases, the electronics associated with the radiation source module 14 may include a radiation intensity sensor and feedback circuitry that together compensate for spurious fluctuations in radiation intensity. In some embodiments (discussed below), the radiation source module 14 may be configured so as to facilitate irradiation of the sample s and effective coupling of the sample and the probe signal p.

The system 10 also includes a data collection and processing module 16 for collecting data indicative of temporal changes in the minority carrier population of the sample s. The data collection and processing module 16 is in communication with both the signal generation module 12 and the radiation source module 14, and can process the data d, including correlating the data with the probe signal p and the radiation r, in order to provide outputs o1, o2, o3 that are indicative of the minority carrier lifetime of the sample. In some cases, the data collection and processing module 16 may be at least partially integrated with the signal generation module 12, with probe signal generation and measurement of the attenuation of the probe signal (or the effort that must be expended to otherwise avoid such attenuation) being done together.

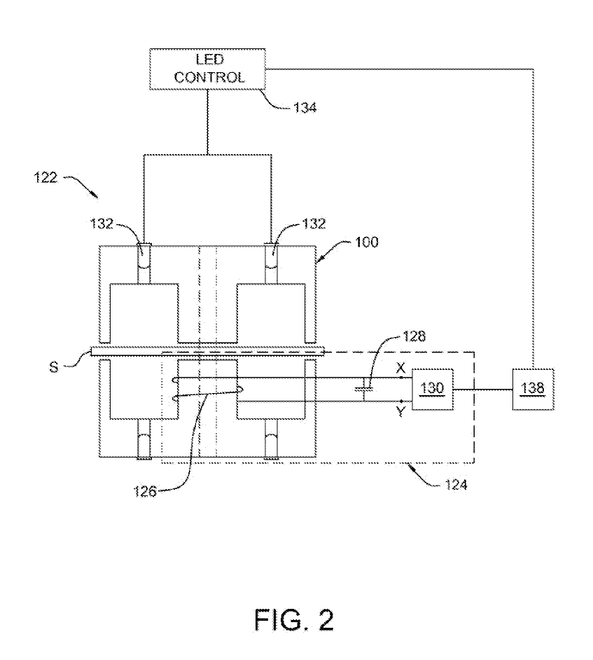

Referring to FIG. 2, therein is shown a tool 122 for measuring minority carrier lifetimes, the tool being configured in accordance with another example embodiment. The tool 122 includes a resonant circuit in the form of a marginal oscillator 124 having an inductor 126 and a capacitor 128. The marginal oscillator 124 is configured to resonate at a measurement frequency fₘ that is associated with a measurement frequency voltage. The marginal oscillator 124 may also include other circuitry and components 130, such as a voltage and/or current source, as discussed in more detail below, that facilitate operation of the marginal oscillator. The tool 122 also includes a ferromagnetic core 100, which is described below.

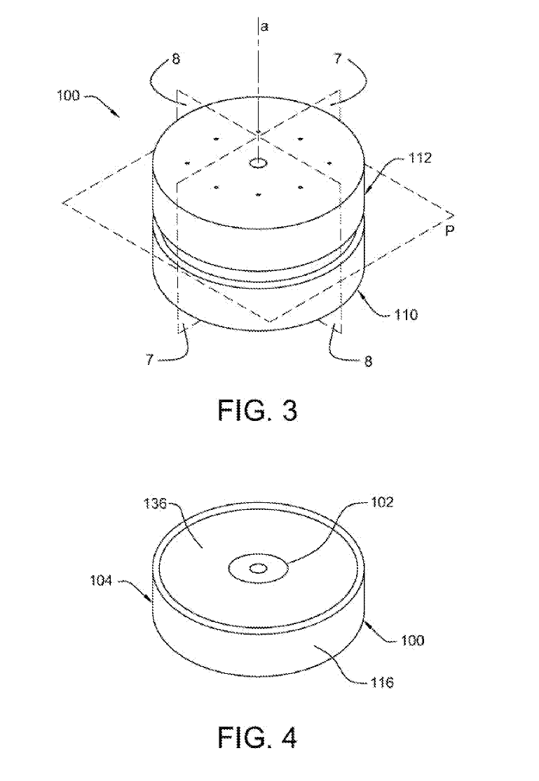

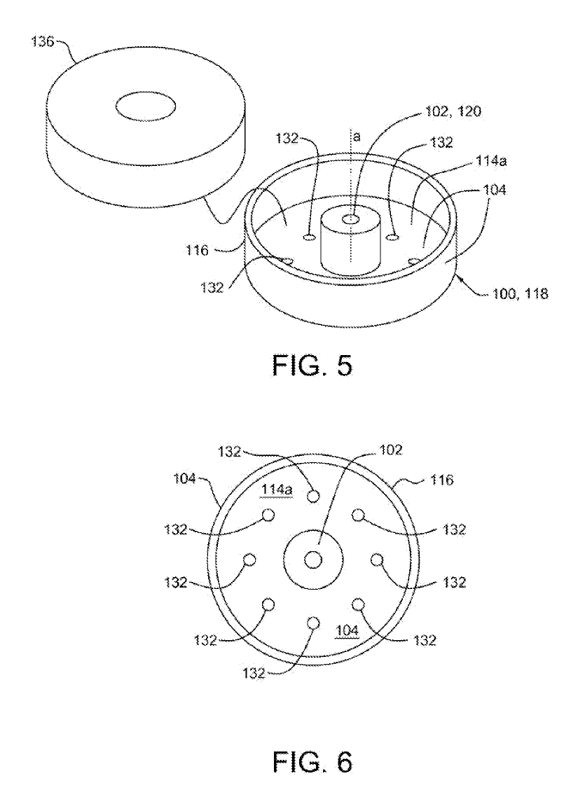

Referring to FIGS. 3-8, the ferromagnetic core 100 can have a first portion 102 and a second portion 104, with the first portion defining a gap 106. The second portion 104 may also define a gap 108 that is aligned with the gap 106 in the first portion 102. The core 100 can include opposing first 110 and second parts 112, with each of the first and second parts forming at least part of the first portion 102 and at least part of the second portion 104. In some embodiments, the first and second parts 110, 112 may be independent of one another and generally symmetrical across a plane p directed along the gap 106 (and also the gap 108). Such a configuration may allow for a sample in the form of a wafer to be disposed in the gap 106 while providing clearance for the portions of the sample that are laterally spaced apart from the portion in the gap. The core 100 may additionally, or alternatively, be generally radially symmetric about a longitudinal axis a defined by the first portion 102.

In some embodiments, the first and second parts 110, 112 may respectively include generally planar bases 114a, 114b. The first portion 102 may extend generally perpendicularly from each of the bases 114a, 114b. The second portion 104 may form a generally annular flange 116 that extends generally perpendicularly from each of the bases 114a, 114b and also circumferentially around the first portion 102. In such embodiments, each of the first and second parts 110, 112 assumes the shape of what is commonly referred to as a “pot core,” where a central post rises from a base plate and is surrounded by an annular flange. The core 100 would then be composed (at least in part) of opposing pot cores 118, with the first portion 102 including the central posts 120 of each of the pot cores and the second portion 104 including the base plates 114a, 114b and the annular flanges 116 of each of the pot cores.

Each of the first and second portions 102, 104 can be configured to respectively direct therealong a magnetic field B established by the inductor 126 when the marginal oscillator 124 is operating. For example, the inductor 126 may include at least one coil that extends circumferentially around the first portion 102. If needed, the coil can be electrostatically shielded from the first portion 102.

Referring to FIGS. 2-8, the first portion 102 may tend to inhibit lateral spreading of the magnetic field B as it is directed along the first portion and to direct the magnetic field generally uniformly across the gap 106. The second portion 104 may be configured so as to direct the magnetic field, in conjunction with the first portion 102, into a closed loop. Of course, magnetic field lines always form closed loops, whether or not any bodies or forces act to direct the field, but the first and second portions may act to specifically direct the magnetic field B in a manner the magnetic field would not otherwise experience. The first and second parts 110, 112 may be coupled to a supporting structure (not shown) that serves to hold the two parts of the core 100 in opposition to one another. The supporting structure may be formed by either a ferromagnetic or non-ferromagnetic material, and may be either conducting or insulating and in any case has little effect on the shaping of the magnetic field B by the core 100.

The tool 122 may further include a radiation source, such as one or more LEDs 132. The LEDs 132 can be configured to irradiate an area proximal to the gap 106 in the first portion 102. The LEDs 132 can extend through one or both of the bases 114a, 114b so as to be disposed between the first portion 102 and the flange 116. The LEDs 132 may be configured to emit radiation intermittently at a switching frequency fₛ. For example, the operation of the LEDs 132 may be controlled by an LED controller 134, which can supply power to the LEDs and can therefore control the intensity and timing (i.e., the times when the LEDs are and are not active) of illumination. The LED controller 134 can include or communicate with an oscillator oscillating at the switching frequency fₛ, such that the LEDs are activated and deactivated at the switching frequency. While connection is only shown between the LED controller 134 and a subset of the LEDs 132 shown in FIG. 8, it should be apparent that all of the LEDs could be connected to the LED controller, or, multiple LED controllers could be employed.

The LEDs 132 may be arranged, for example, in a ring pattern around the first portion 102 so as to irradiate a generally radially symmetric area around the gap 106. Respective LEDs 132 may be configured to emit radiation of different wavelengths. For example, each base 114a, 114b may include LEDs 132 that emit radiation of a certain wavelength, such that radiation of a first wavelength is emitted from the LEDs contained in one base and radiation of a second wavelength is emitted from the LEDs contained in the other base. Alternatively, each base 114a, 114b may include respective LEDs configured to emit radiation at multiple wavelengths, such that, for example, one base has respective LEDs that emit radiation at a first and a second wavelength and the other base has respective LEDs that emit radiation at a third and a fourth wavelength. Regardless of whether a base 114a, 114b includes LEDs 132 emitting a uniform wavelength of radiation or a variety of wavelengths, the LEDs can be arranged so as to emit radially symmetric radiation, for example, by interleaving radially symmetric rings of LEDs of different wavelengths.

In some embodiments, sequentially irradiating a sample with radiation of respectively different wavelengths may have advantages. For example, radiation of different wavelengths may penetrate a sample to different depths. For cases where radiation penetrates relatively deep into the sample, the effect of the interaction between the radiation and the sample surface will tend to be less significant with respect to the total measurement than in cases where the radiation remains relatively shallow. As such, utilizing LEDs of differing radiation frequency can allow for characterizing the surface of a sample. Or conversely, to remove surface recombination effects and identify more clearly the bulk recombination lifetime.

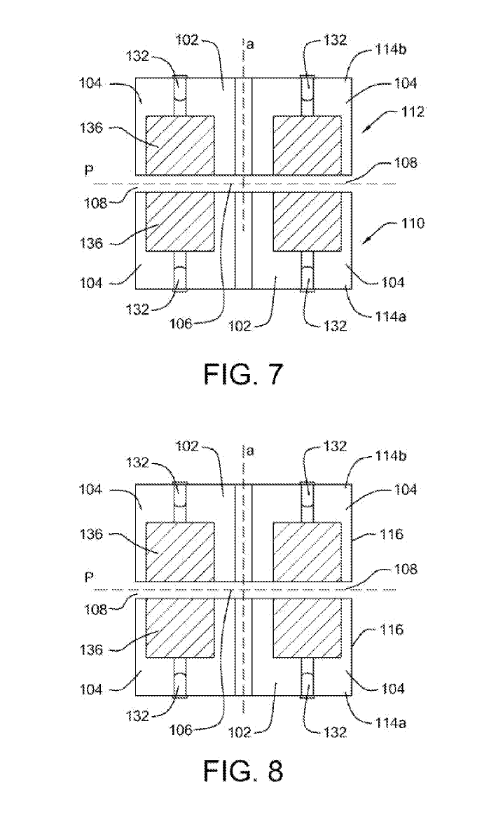

FIGS. 7 and 8 show that the core 100 and/or radiation source may also include an optical diffuser 136 that is disposed adjacent to the LEDs 132 and in the space between the first portion 102 and the flange 116. The diffuser 136 acts to receive the discrete outputs of the LEDs 132 and to emit more spatially uniform radiation.

In certain embodiments, each LED 132 can be a radiation source that includes a single housing including at least two light emitting diodes having different respective wavelengths. The single housing can be disposed relative to, affixed to, or embedded into the core 100. Various LED colors can be integrated into a single LED housing with a final lens (e.g., a single bulb with multiple electrical leads, 2 per color).

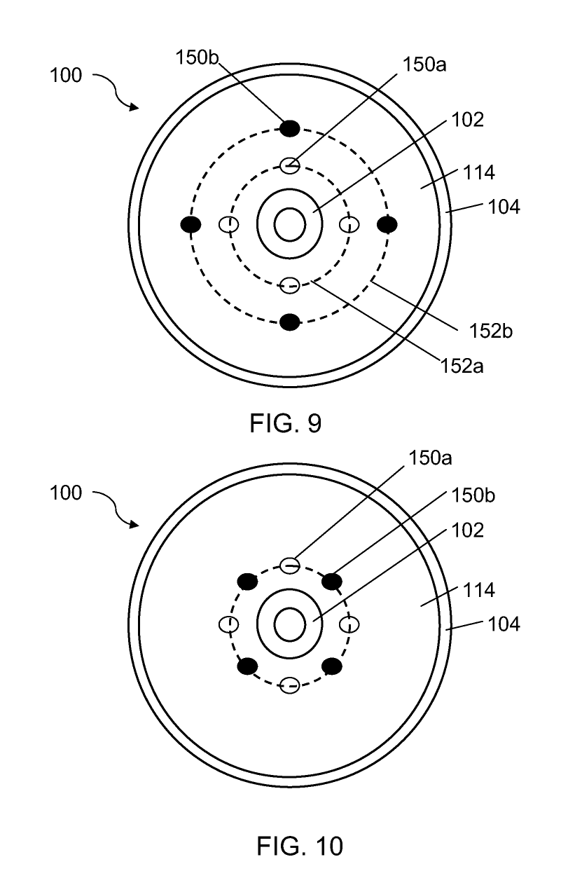

FIG. 9 shows an embodiment of the core 100 that is configured to deliver two or more wavelengths of light to a substrate. The core member 100 includes a plurality of radiation sources 150x disposed radially outward from and circumferentially around the post of the member. The plurality of radiation sources 150x are arranged in two circumferential rings 152a, 152b around the post. Additional circumferential rings can be used depending on the application. For example, a third wavelength can be included with said additional ring of plurality of radiation sources.

In FIG. 9, a first circumferential ring 152a includes first sources 150a having a first wavelength. A second circumferential ring 152b includes second sources 150b having a second wavelength different than the first wavelength. The core member 100 includes a first portion 102 (e.g., a post) and a second portion 104 (e.g., an outer wall or flange of the member). The plurality of radiation sources 150x can be disposed relative to, affixed to, or embedded into a base 114 or a surface of the core member 100. Any pattern of spacing radiation sources 150x along a circumferential ring 152x or relative to one another along adjacent circumferential rings 152x can be utilized. A third wavelength can be included in a third circumferential ring.

FIG. 10 shows another embodiment of the core 100 configured to deliver two or more wavelengths of light to a substrate. The core member 100 includes a plurality of radiation sources 150x disposed radially outward from and circumferentially around the post of the member. The plurality of radiation sources 150x are arranged so that first sources 150a having a first wavelength are interleaved with second sources 150b having a second wavelength different than the first wavelength.

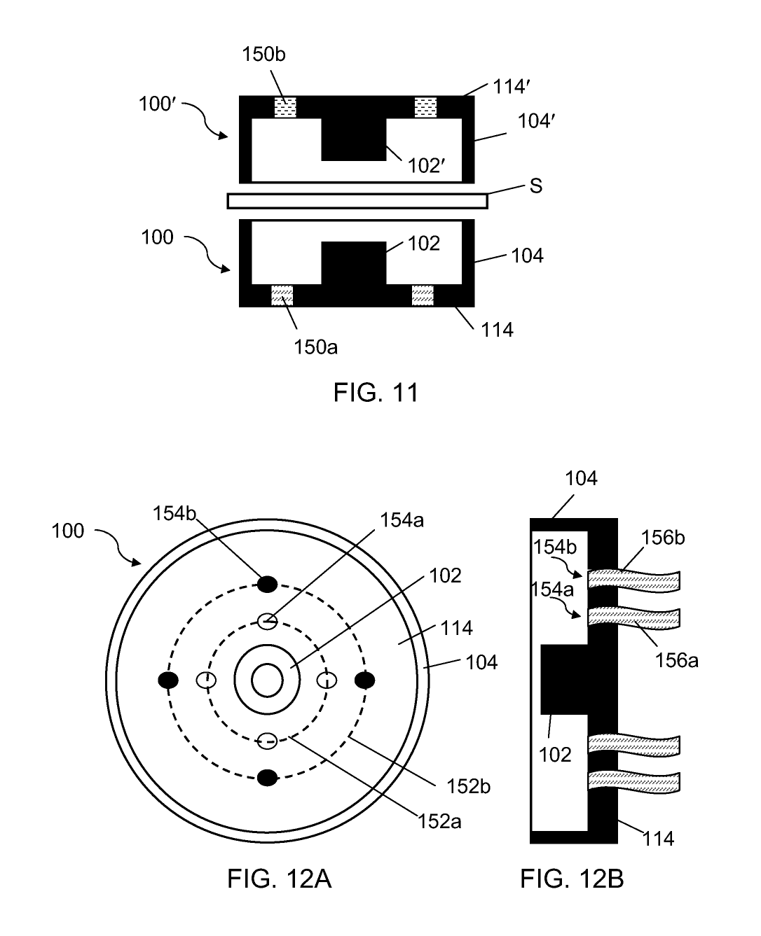

FIG. 11 shows an apparatus including a first core member 100 and a second core member 100′ including a second, first portion 102′ disposed at its center and a second surface (e.g., base 114′) extending to a second, second portion 104′ (e.g., an outer wall or flange of the member). The second core member 100′ defines a second gap between the second post and the second outer wall. The substrate S is disposed between the core member 100 and the second core member 100′. A second plurality of radiation sources 150b are disposed radially outward from and circumferentially around the second post 102′ of the second core member 100′. The plurality of radiation sources 150a have a first wavelength that is different than a second wavelength of the second plurality of radiation sources 150b.

In certain embodiments, the plurality of radiation sources 150x includes a first source 150a having a first wavelength having a 90% penetration depth that is less than 20 micrometer and a second source 150b having a second wavelength having a 90% penetration depth that is greater than 180 micrometer. The first source 150a can have a first wavelength having a 90% penetration depth that is less than 3 micrometer.

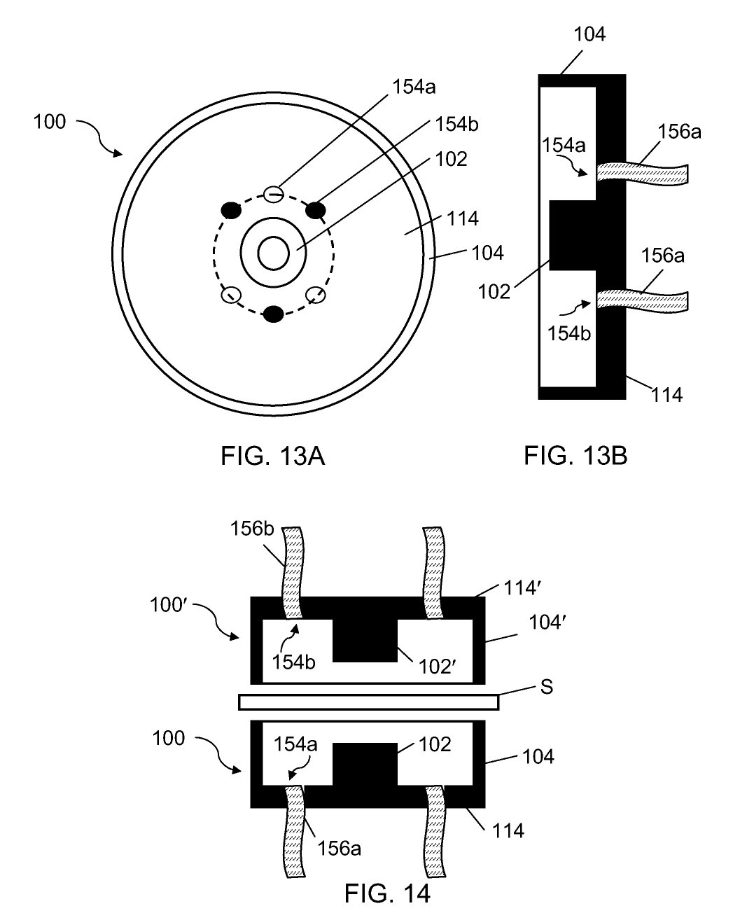

FIG. 12 and FIG. 13 show embodiments of core member 100 where instead of radiation sources 150x, a plurality of ports 154x is defined in the member 100 radially outward from and circumferentially around the post 102 of the member. A plurality of optical waveguides 156x is coupled to one or more radiation sources (not shown). Each optical waveguide 156x is configured to deliver the radiation to the substrate through one of the plurality of ports 154x. In various embodiments, the plurality of optical waveguides 156x can be an optical fiber, an optical fiber bundle, a light guide, a liquid light guide, a reflective light guide or a hollow waveguide.

FIGS. 12A and 12B show an embodiment where the plurality of ports 154x are arranged in two circumferential rings 152x disposed around the post 102. A first plurality of optical waveguides 156a are coupled to a first source having a first wavelength. Each waveguide 156a of the first plurality of optical waveguides is configured to deliver radiation from the first source to the substrate through one of the ports 154a in a first circumferential ring 152a. A second plurality of optical waveguides 156b is coupled to a second source having a second wavelength. Each waveguide 156b of the second plurality of optical waveguides is configured to deliver radiation from the second source to the substrate through one of the ports 154b in a second circumferential ring 152b. More than two circumferential rings can be used. For example, a third wavelength can be included in a third circumferential ring.

FIGS. 13A and 13B show an embodiment where first ports 154a are interleaved with second ports 154b. A first plurality of optical waveguides 156a is coupled to a first source having a first wavelength. Each waveguide 156a of the first plurality of optical waveguides is configured to deliver radiation from the first source to the substrate through one of the first ports 154a. A second plurality of optical waveguides 156b is coupled to a second source having a second wavelength. Each waveguide 156b of the second plurality of optical waveguides is configured to deliver radiation from the second source to the substrate through one of the second ports 154b.

FIG. 14 shows an apparatus including a first core member 100 and a second core member 100′ including a second, first portion 102′ disposed at its center and a second surface (e.g., base 114′) extending to a second, second portion 104′ (e.g., an outer wall or flange of the member). The second core member 100′ defines a second gap between the second post and the second outer wall. The substrate S is disposed between the core member 100 and the second core member 100′. A second plurality of ports 154b is defined in the second core member 100′ radially outward from and circumferentially around the second post 102′ of the member. A second plurality of optical waveguides 156b is coupled to one or more radiation sources. Each optical waveguide 156b is configured to deliver the radiation to the substrate through one of the second plurality of ports 156b. The radiation sources are coupled to the plurality of optical waveguides 156a having a first wavelength that is different than a second wavelength of the radiation sources coupled to the second plurality of optical waveguides 156b.

In operation, the minority carrier lifetime measurement tool 122 can be configured to receive a sample s, such as a wafer of semiconductor material, so that a portion of the sample is disposed within the gap 106. In this way, a magnetic field established by the inductor 126 of a functioning marginal oscillator 124 may extend generally uniformly through the portion of the sample s disposed in the gap 106, thereby electromagnetically coupling the sample into the marginal oscillator. This electromagnetic coupling of the sample s into the oscillator 124 tends to induce eddy currents in the sample, which eddy currents dissipate energy from the oscillator 124. The magnitudes of the eddy currents and resulting energy losses are related to the conductivity σ and thickness t of the sample s, which conductivity relates to the product of the density of all of the carriers in the sample and the mobility of those carriers.

The tool 122 allows for monitoring the losses experienced by the oscillator 124 in several ways. In one case, the voltage across the marginal oscillator 124 (e.g., the measurement frequency voltage or the voltage difference between points x and y of FIG. 8) can be monitored for variation. In all cases, the marginal oscillator 124 necessarily includes a current source (not shown in FIG. 8, but discussed in more detail later) configured to supply a current sufficient to maintain the voltage across the marginal oscillator 124. This current is herein sometimes referred to as a “drive current,” and the associated current source as a “drive current source.” The output of the current source is therefore representative of losses in the oscillator 124, and this quantity is monitored. More details regarding the theory underlying such measurements are provided in U.S. Pat. No. 4,286,215 to Miller et al., the content of which is incorporated herein by reference in its entirety.

The density of minority carriers in the sample s can be modulated using the LEDs 132. The sample s can be illuminated with radiation of frequency equal to or higher than the frequency required to excite electrons from the valence band across the band gap into the conduction band (“above bandgap” radiation), thereby generating hole-electron pairs in the sample. The presence of these additional carriers results in increased conductivity (referred to as “photoconductivity”) of the sample. At the onset of irradiation, the conductivity increases monotonically, and upon cessation of irradiation, the conductivity exponentially decreases to its value in the absence of radiation (i.e., its equilibrium value). The increase in conductivity following the onset of irradiation can be described by

Δσ(t)∝μGτ(1−e^{--t/τ}) (1)

where Δσ is the change in conductivity of the sample brought about by photoconductivity, μ is the carrier mobility, τ is a recombination time constant that is equal to the effective minority carrier lifetime, and t is the time elapsed since turning on the LED, when a wafer has a net zero total current flowing. It is noted that a somewhat similar equation governs the decrease in conductivity of a sample following the cessation of irradiation.

The tool 122 may be configured so as to enable several different methods of measuring minority carrier lifetime. A first method is that of photoconductive decay (PCD), in which the sample being characterized is intermittently illuminated with above bandgap radiation. The intermittent illumination can be provided at a switching (i.e., on/off) frequency fₛ that is on the order of or lower than the inverse of the (expected) effective minority carrier lifetime Immediately after each cessation in irradiation, the decrease in conductivity σ of the sample s as a function of time can be measured. By fitting to this data an exponential or multiple exponentials to the decay, effective minority carrier lifetime can be determined.

The PCD method exhibits the beneficial feature of being “self-calibrating,” meaning the results obtained using this method are not relative, but are objective measurements of carrier lifetime. However, this method requires a measurement system for which response is very fast compared to the sample lifetimes. As such, while the PCD method is readily applicable to the determination of lifetime in large semiconductor single crystal ingots and/or samples having a relatively long effective minority carrier lifetime (e.g., on the order of 10 μs or more), the method tends to be less useful for measuring effective minority carrier lifetimes in samples in which the effective minority carrier lifetime is relatively short (e.g., ≦about 5 μs), since typically the sensitivity of such samples is insufficient to yield an acceptable signal-to-noise ratio, or the system response, such as that determined by the sampling rate of the electronics and rate of fall of the illumination source cut-off characteristics, is on order of the inverse of the minority carrier lifetime under test.

A second method of measuring carrier lifetime that is enabled by a tool configured as described above is that described in U.S. Pat. No. 4,286,215 to Gabriel L. Miller, the content of which is incorporated herein by reference in its entirety. As with the PCD method, this method, referred to herein at the “GTAU method,” involves intermittently, at a switching frequency fₛ that is on the order of or lower than the inverse of the (expected) effective minority carrier lifetime, irradiating the sample s with above bandgap radiation. However, in the GTAU method, the conductivity σ of the sample s is measured for times that are subsequent to an activation and a deactivation of the LEDs 132 by a time which is large compared to T. The conductivities being measured are therefore effectively steady state conductivities for an illuminated state or otherwise known as “true steady state photoconducance or photoconductivity” (i.e., the conductivity when the LEDs 132 are emitting radiation) and for a nonilluminated or “darkened” state, respectively. From Equation (1), it is apparent that the difference between the steady state conductivity in the illuminated and darkened states is proportional to the product μGτ (hence the name Gtau). Furthermore, the increase in conductivity or photoconductivity at the outset of irradiation of a sample will asymptotically approach a steady state value (as will the decrease in conductivity upon cessation of irradiation).

Under appropriate conditions (as discussed above), either or both the PCD method and the GTAU method may be used in conjunction with the minority carrier lifetime measurement tool 122. The data acquisition and processing components 138 can be configured to receive data from the marginal oscillator 124 (such as an indication of the voltage across the marginal oscillator, i.e., the measurement frequency voltage, or the magnitude of the drive current required to maintain the amplitude of oscillations of the oscillator at the nominal amplitude). The data acquisition and processing components 138 can also be configured to receive data from the LED controller 134 indicative of the intensity and switching frequency of the LEDs 132. All of these data can be stored for later analysis or used to provide outputs to a user regarding the conductivity and photoconductivity of a sample.

In some embodiments, the sample s may be iteratively repositioned in the tool 122 such that different portions of the sample are disposed in the gap between the two halves of the ferrite pot core 106. The conductivity of the sample s can be remeasured for each repositioning of the sample. The data acquisition and processing components 138 can be configured to receive data regarding the movements of the sample, in addition to the conductivity data, such that minority carrier lifetime can be correlated to spatial position within the sample to create a minority carrier lifetime “map.”

As mentioned above, a tool configured in accordance with the above-described embodiments may tend to direct a magnetic field substantially uniformly across the gap defined by the first portion of the core. In some cases, this may reduce the sensitivity of measurements to spacing of the sample within the gap and relative to either portion of the first portion of the core. It is also noted that the capability of performing both the GTAU and PCD measurement methods in a single tool, as may be provided in embodiments configured in accordance with the above discussion, has significant benefits. As mentioned earlier, the GTAU method has a relatively superior SNR and is able to measure shorter minority carrier lifetimes when compared to the PCD method, upon applying a relative calibration. However, the results of the GTAU measurements are not absolute, as they depend on light intensity, and deviations from said calibration would indicate a quantitative metric of increase reflection losses or lower light transmittance through the wafer surface. Alternatively, the PCD method, while being relatively poor in both SNR and ability to measure short carrier lifetimes, is an absolute measurement and can be used to apply a “natural calibration” of the true steady state photoconductance GTAU. As such, these methods can be complimentary, with the PCD method serving to calibrate the GTAU method results and the GTAU method then providing high quality measurements for short minority carrier lifetimes.

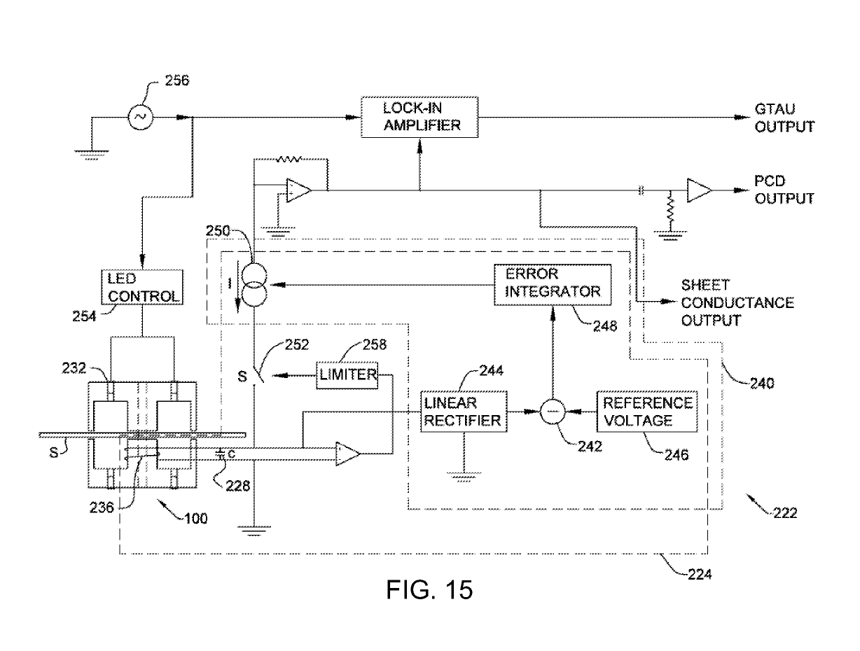

FIG. 15 shows a tool 222 for measuring minority carrier lifetime, the tool being configured in accordance with another example embodiment. The tool includes a marginal oscillator 224 having an inductor 226 and a capacitor 228 and is configured to resonate at a measurement frequency fₘ that is associated with a measurement frequency voltage. The inductor 226 can be configured so as to facilitate electromagnetic coupling of a semiconductor sample s to the marginal oscillator 224, for example, by being disposed such that magnetic fields produced by the inductor extend into the sample. The core 100, as discussed above, enhances the electromagnetic coupling of the sample s into the marginal oscillator 224.

The marginal oscillator 224 necessarily includes a voltage regulation circuit 240. The voltage regulator 240 may include a comparator 242 that outputs the difference between the voltage across the oscillator 224 (as output by a rectifier 244) and a reference voltage source 246. The output from the comparator 242 is passed to an error integrator 248, which controls a current source (a drive current source) 250 to output a current (a drive current) intended to minimize the difference between the voltage across the inductor 226 and the reference voltage source 246.

Embodiments of the marginal oscillator 224 may provide enhanced performance as compared to that for previously disclosed semiconductor minority carrier lifetime measurement systems. For example, embodiments may show an improved signal-to-noise ratio (SNR) of the oscillator.

The tool 222 also includes one or more LEDs 232 in communication with a LED driver 254 configured to control the operation of the LEDs. The LED driver 254 can receive a signal from an oscillator 256 such that the switching frequency fₛ of the LEDs 232 conforms to the frequency of oscillation of the oscillator. The LEDs 232 can be driven by the LED driver 254, for example, at a switching frequency fₛ of (nominally) 100 Hz (i.e., five milliseconds “on” followed by five milliseconds “off”).

In operation, the tool 222 may be configured to receive a sample s of semiconductor material, such as a semiconductor wafer, such that the sample is electromagnetically coupled into the marginal oscillator 224 oscillating at a measurement frequency fₘ associated with a measurement frequency voltage. As the oscillator 224 transfers energy into the sample, the drive current is automatically adjusted by the voltage regulator 240, so as to maintain constant the measurement frequency voltage. As discussed above, the drive current being supplied by the drive current source 250 is representative of the sheet conductivity of the sample being measured.

The sample s can be intermittently irradiated with above bandgap radiation. The intermittence can be at a switching frequency fₛ that is on the order of or lower than the inverse of minority carrier lifetime for the sample. For each commencement and cessation of irradiation of the sample s, the conductivity of the sample will vary, as will, consequently, the load on the oscillator 224. This change in load on the oscillator 224 will cause the amplitude of the oscillations to tend to decrease, and the drive current source 250 acts to maintain (i. e., stabilize) the measurement frequency voltage across said resonant circuit constant. The drive current provided by the drive current source 250 can be continuously monitored in order to determine the sample conductivity and to determine therefrom the minority carrier lifetime of the sample.

Monitoring of the drive current can include storing, perhaps with a data acquisition device, drive current data as a function of time and the state of the LEDs 232 (e.g., the intensity of radiation emanating therefrom). The measurement frequency voltage may also be recorded for correlation with the drive current data. The drive current may be sampled at a sample rate that is higher than the inverse of minority carrier lifetime for the sample, thereby allowing for sufficient data collection to enable PCD curve-fitting for the decrease in conductivity immediately after ceasing irradiation. For example, the drive current can be digitized by a high speed analog-to-digital converter (e.g., providing 10⁶ conversions per second). In some embodiments, the sampling rate for drive current data may be synched with the oscillator 256 such that a high sampling rate is employed around the time the LEDs 232 are turned on and off, and a lower sampling rate is employed at other times.

The data collected by the tool 222 can be provided in a variety of ways. Temporal drive current data may be fit by Equation (1) and a related equation for the decay of the signal in order to obtain minority carrier lifetime directly for long lifetime samples. This is referred to as the “PCD output” (see FIG. 15). Alternatively, given that the drive current modulation is proportional to minority carrier lifetime, the drive current itself can be appropriately amplified (with, e.g., a lock-in amplifier synchronized with the oscillator 256) so as to indicate minority carrier lifetime. This output is referred to as the “GTAU output.” As still another alternative, the conductivity of the sample (from which the GTAU output was derived”) can be reported. This output is referred to as the “sheet conductance output,” And is properly scaled or calibrated by using a single sample of known sheet conductance, also known as the inverse of sheet resistance. It is noted that any or all of these outputs can be provided essentially simultaneously for a single sample.

Overall, a system configured in accordance with the above-described embodiments may enable the measurement of semiconductor minority carrier lifetimes, from less than one tenth of a microsecond to 10's of milliseconds, with each measurement of four calculated values taking 16.6 milliseconds for a single average. Measurements may be performed using the PCD method and the GTAU method, with the PCD method providing inherent calibration and the GTAU method facilitating short lifetime measurements or a measure of a “photoconductance index” in the true steady state and providing improved overall SNR when scaled to a time scale. Sheet conductance may also be reported, and outputs from all four measurements (PCB, PCD, GTAU, and sheet conductance) may be available to a user.

Fast programmable diodes and multiple wavelengths can be used to uniquely differentiate near surface information for minority carrier lifetimes as compared to the bulk, along with a unique means of performing trap state compensation with sub band gap light, or alternatively, by turning off the above band gap illumination to a nonzero level during the LED off period (known as modulation depths of 1% to 99%, 50% being typical). A first wavelength can have a 90% penetration depth that is less than or equal to 20 micrometer (e.g., 3 micrometer), and a second wavelength can have a 90% penetration depth of greater than or equal to 180 micrometer.

The radiation sources can be concentric rings of LED's that turn on and off at programmed modulation times that differ sufficiently to measure and differentiate the response of one color versus the other. Alternatively, the wavelengths can be used in concert where the full wafer probing wavelength is held at a constant level, as the near surface probing wavelength is modulated on and off. A given color array of LED's can be on a single side of the wafer and a second color LED array can be disposed on the other. A shorter wavelength can be used as a surface probe, while a longer wavelength can be used as a full wafer probe. The diode array can be modulated with rise and fall times of 800 nanosecond or less (e.g., 100 nanosecond or less) and programmed with a long on and off duty cycle of 0.5 to 1.5 millisecond. This type of modulation can be represented by a square wave or a pulse train of top hats. By controlling the phase between a multiplicity of square waves, photoconductance signals of multiple colors can be acquired bringing about varying information from the depth of the wafer.

The fast rising edge of the LED during turn on illumination, after digital sampling and amplification, reflects the photoconductance build up lifetime; the long plateau of the square wave under constant illumination yields a low bandwidth noise measurement of the “true steady state” lifetime or “GTau” method. The short falling edge of the diode array turning off the illumination leads to an absolute measurement of minority carrier lifetime recombination. PC build-up can be used in addition to PC decay lifetime to provide a defect detection technique.

The nature of PC build up is the initial response a semiconducting material presents to a fast changing illumination signal. In direct analogy to low pass filter theory, the fast modulated signal of the LED array is partially attenuated, allowing slower frequency components of the rising edge to pass onto the detection circuitry, whose frequency response is faster by 5 to 10 times than the inverse minority carrier lifetime under test. Using a total energy picture, the wafer offers a type of reactance to store the energy and delay the response of the semiconductor to the fast excitation of light making up the surface probe and the full wafer probe. The simultaneous measurement of PCB and PCD brings about a unique probe for imperfections found in semiconducting wafers, such as solar silicon wafers of mono or poly crystal type. Imperfections of interest can be residual metal impurities leading to shallow or deep trap centers in silicon, crystallographic defects and point defects due to new manufacturing techniques of solar wafers, such as residual strain due to novel wafer recrystallization or zone melt refining techniques, mixed phases of amorphous to polysilicon in low crystal quality solar wafers, or variation in incorporated and or activated hydrogen in amorphous, microcrystalline and polysilicon wafers.

The difference in PCB and PCD lifetime that manifests as rising and falling curves with differences in 1/e response time for a given defective wafer can be measured. PCB and PCD can both have exponential fitted curves that differ and define an asymmetry in turn on to turn off 1/e response time. Depending on the physical nature of the defect, the wafer can present faster response or shorter response between the two signals. In the case of a perfect crystal, the PCB will be equivalent to the PCD.

The true steady state lifetime measurement has a direct linear relationship to the shortest response time as determined by the PCB or PCD full wafer probe under low light injection level conditions. A self-calibration technique allows a measurement technique to operate in steady state without the need to separately measure the illumination power for the purpose of determining the generation rate, as is common practice in “RFPCD flash lamp systems.” This second measurement requirement is a short coming of existing quasi steady state approaches. A single measurement system can span the widest dynamic range beginning at approximately 100 nanosecond and reaching upwards of 10's of milliseconds.

A secondary or tertiary ring of LED's with wavelength greater than 1.1 micron's can be integrated in measurement systems with a constant level of background illumination to act as a bias light. This effective bias light simultaneously illuminates the regions along with the modulated light probing (surface and full wafer), but is not absorbed in a band to band fashion by the semiconductor because the corresponding energy transitions allowed are sub band gap in nature due to the chosen wavelength. The wavelength is instead selected to allow band to defect state transitions to occupy defect states or empty defect state depending on semiconductor type. The defect states become ineffective at trapping photogenerated carriers from the band to band transition resulting from the modulated LED surface and full wafer probes. Trap states can be quenched and do not contribute an erroneously long lifetime that is typical of shallow trap signatures in minority carrier lifetime data from other existing techniques when using low light injection level conditions.

A technique can include electromagnetically coupling a substrate into an inductance-capacitance resonant circuit formed from a member comprising a ferromagnetic material, an inductor and the substrate. The substrate can be illumated to cause photoconduction in the substrate. A drive current of the inductance-capacitance resonant circuit can be measured while illuminating to determine photoconductance build-up.

Another technique can be used to measure minority carrier lifetime from a plurality of depths within a substrate, which is electromagnetically coupled into an inductance-capacitance resonant circuit formed from a member comprising a ferromagnetic material, an inductor and the substrate. The substrate is illuminated with a first wavelength to probe a surface of the substrate and illuminated with a second wavelength longer than the first wavelength to probe the bulk of the substrate.

The drive current of the inductance-capacitance resonant circuit can be measured while switching the illumination to determine photoconductive decay. The substrate can be illuminated with above bandgap radiation and/or with sub-band gap radiation to populate any defect states of the substrate. The illumination can be modulated with a rise and fall time of less than or equal to 800 nanosecond (e.g., less than or equal to 100 nanosecond).

Several alternative embodiments of the invention may be possible while maintaining the principles (and benefits) of the measurement system described here. Specifically, alternative configurations of the ferromagnetic core may include, e.g., opposing U-shaped or E-shaped cores, instead of the opposing split cup core described here. In evaluating the appropriateness of these (and other) alternative embodiments there are three key parameters that need to be evaluated; the tightness of the inductive coupling to the semiconductor sample, the uniformity of the light source, and the shielding to signals arising from any semiconductor material outside the desired measurement area. It is maintained here that the split cup core embodiment may enable advantages with respect to one or more of these key parameters as compared to alternative configurations. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

What is claimed is:

1. An apparatus comprising:
a member comprising a ferromagnetic material, the member including a post disposed at its center and a surface extending to an outer wall, the member defining a gap between the post and the outer wall;
an inductance-capacitance resonant circuit configured to resonate at a measurement frequency, the circuit including an inductor disposed relative to the post;
a substrate disposed relative to the member, the substrate electromagnetically coupled to the inductor; and
a plurality of radiation sources disposed radially outward from and circumferentially around the post of the member.

2. The apparatus of claim 1 wherein the plurality of radiation sources comprises two circumferential rings disposed around the post, a first circumferential ring including first sources having a first wavelength and a second circumferential ring including second sources having a second wavelength different than the first wavelength.

3. The apparatus of claim 1 wherein the plurality of radiation sources comprises first sources having a first wavelength interleaved with second sources having a second wavelength different than the first wavelength.

4. The apparatus of claim 1 wherein each radiation source includes a single housing including at least two light emitting diodes having different respective wavelengths.

5. The apparatus of claim 1 further comprising:
a second member comprising the ferromagnetic material, the second member including a second post disposed at its center and a second surface extending to a second outer wall, the second member defining a second gap between the second post and the second outer wall, the substrate disposed between the member and the second member; and
a second plurality of radiation sources disposed radially outward from and circumferentially around the second post of the second member, the plurality of radiation sources having a first wavelength that is different than a second wavelength of the second plurality of radiation sources.

6. The apparatus of claim 1 wherein the plurality of radiation sources comprises a first source having a first wavelength having a 90% penetration depth that is less than 20 micrometer and a second source having a second wavelength having a 90% penetration depth that is greater than 180 micrometer.

7. The apparatus of claim 6 wherein the first source has a first wavelength having a 90% penetration depth that is less than 3 micrometer

8. The apparatus of claim 1 wherein each radiation source is a light emitting diode.

9. A method comprising:
electromagnetically coupling a substrate into an inductance-capacitance resonant circuit formed from (i) a member comprising a ferromagnetic material, (ii) an inductor and (iii) the substrate;
illuminating the substrate to cause photoconduction in the substrate; and
measuring a drive current of the inductance-capacitance resonant circuit while illuminating to determine photoconductance build-up.

10. The method of claim 9 further comprising measuring the drive current of the inductance-capacitance resonant circuit while switching the illumination to determine photoconductive decay.

11. The method of claim 9 further comprising illuminating the substrate with above bandgap radiation.

12. The method of claim 9 further comprising illuminating the substrate with sub-band gap radiation to populate any defect states of the substrate.

13. The method of claim 9 further comprising modulating the illumination with a rise and fall time of less than or equal to 800 nanosecond.

14. A method of measuring minority carrier lifetime from a plurality of depths within a substrate, comprising:
electromagnetically coupling the substrate into an inductance-capacitance resonant circuit formed from (i) a member comprising a ferromagnetic material, (ii) an inductor and (iii) the substrate;
illuminating the substrate with a first wavelength to probe a surface of the substrate; and
illuminating the substrate with a second wavelength longer than the first wavelength to probe the bulk of the substrate.

15. The method of claim 14 further comprising illuminating the substrate with sub-band gap radiation to populate any defect states of the substrate.

16. The method of claim 14 further comprising modulating the illumination of either the first wavelength or the second wavelength with a rise and fall time of less than or equal to 800 nanosecond.

17. The method of claim 14 wherein sources for the first wavelength and for the second wavelength are disposed in two circumferential rings on a surface of the member.

18. The method of claim 14 wherein sources for the first wavelength and for the second wavelength are interleaved in a circumferential ring on a surface of the member.

19. The method of claim 14 wherein sources for the first wavelength and for the second wavelength are disposed in a single housing disposed on a surface of the member.

20. The method of claim 14 wherein first sources for the first wavelength are disposed relative to a first side of the substrate and second sources for the second wavelength are disposed relative to a second, opposing side of the substrate.

21. An apparatus comprising:
a member comprising a ferromagnetic material, the member including a post disposed at its center and a surface extending to an outer wall, the member defining a gap between the post and the outer wall;
an inductance-capacitance resonant circuit configured to resonate at a measurement frequency, the circuit including an inductor disposed relative to the post;
a substrate disposed relative to the member, the substrate electromagnetically coupled to the inductor;
a plurality of ports defined in the member radially outward from and circumferentially around the post of the member; and
a plurality of optical waveguides coupled to one or more radiation sources, each optical waveguide configured to deliver the radiation to the substrate through one of the plurality of ports.

22. The apparatus of claim 21 wherein the plurality of optical waveguides comprise one of an optical fiber, an optical fiber bundle, a light guide, a liquid light guide, a reflective light guide or a hollow waveguide.

23. The apparatus of claim 21 wherein the plurality of ports comprises two circumferential rings disposed around the post, wherein:
a first plurality of optical waveguides are coupled to a first source having a first wavelength, each waveguide of the first plurality of optical waveguides configured to deliver radiation from the first source to the substrate through one of the ports in a first circumferential ring; and
a second plurality of optical waveguides are coupled to a second source having a second wavelength, each waveguide of the second plurality of optical waveguides configured to deliver radiation from the second source to the substrate through one of the ports in a second circumferential ring.

24. The apparatus of claim 21 wherein the plurality of ports comprises first ports interleaved with second ports, wherein:
a first plurality of optical waveguides are coupled to a first source having a first wavelength, each waveguide of the first plurality of optical waveguides configured to deliver radiation from the first source to the substrate through one of the first ports; and
a second plurality of optical waveguides are coupled to a second source having a second wavelength, each waveguide of the second plurality of optical waveguides configured to deliver radiation from the second source to the substrate through one of the second ports.

25. The apparatus of claim 1 further comprising:
a second member comprising the ferromagnetic material, the second member including a second post disposed at its center and a second surface extending to a second outer wall, the second member defining a second gap between the second post and the second outer wall, the substrate disposed between the member and the second member;
a second plurality of ports defined in the second member radially outward from and circumferentially around the second post of the member; and
a second plurality of optical waveguides coupled to one or more radiation sources, each optical waveguide configured to deliver the radiation to the substrate through one of the second plurality of ports, the radiation sources coupled to the plurality of optical waveguides having a first wavelength that is different than a second wavelength of the radiation sources coupled to the second plurality of optical waveguides.
